(19) United States
(12) Patent Application Publication
(10) Pub. No.: US 2026/0322396 A1
(43) Pub. Date: Oct. 15, 2026

(54) FREQUENCY-TO-DIGITAL CONVERTER BASED ON TRUNCATED GRAY ENCODING

(71) Applicant: Infineon Technologies AG, Neubiberg (DE)

(72) Inventors: Andres Quintero Alonso, Villach (AT); Luis Hernandez-Corporales, Madrid (ES); Victor Medina, Madrid (ES)

(21) Appl. No.: 19/174,699

(22) Filed: Apr. 9, 2025

(51) Int. Cl. H03M 7/16; H03M 1/28; H03M 1/50

(52) U.S. Cl. CPC H03M 7/16; H03M 1/285; H03M 1/508

(57) ABSTRACT

In accordance with an embodiment, a method includes generating N phases from a ring oscillator circuit having an odd number of stages, where N is an odd integer 3 or greater; encoding the N phases using a combinatorial truncated Gray code encoder circuit to produce M truncated Gray encoded bits, where fewer than 2^{M} Gray codes are used to encode the N phases; converting the M truncated Gray encoded bits to binary using a Gray code to binary encoding circuit to form a binary output; and forming a first difference of the binary output.

### TECHNICAL FIELD

The present invention relates generally to a system and method for an electronic system, and, in particular embodiments, to a system and method for a frequency-to-digital converter based on truncated gray encoding.

### BACKGROUND

Voltage-controlled oscillator-based analog-to-digital converters (VCO-ADCs) have emerged as an attractive alternative to conventional switched-capacitor ADCs, particularly for applications such as sensor interfaces and biomedical systems. VCO-ADCs achieve primarily digital implementation through logic circuits, making them especially suitable for advanced CMOS processes where analog performance is challenging to maintain.

A VCO-ADC architecture typically employs a ring oscillator connected to a frequency-to-digital converter (FDC) that utilizes thermometer encoding. The ring oscillator performs the initial voltage-to-frequency conversion, while the FDC quantizes the oscillator's phase progression to generate the digital output. In multi-phase implementations, each stage of the ring oscillator provides a phase output that is processed by the FDC circuitry. The FDC traditionally requires multiple flip-flops and logic gates per phase to detect signal transitions and combine the phase information into a digital output.

The digital hardware complexity of VCO-ADCs presents challenges for achieving power and area efficiency, particularly as resolution requirements increase. The first-order noise shaping characteristics of the open-loop VCO-ADCs necessitate either high oscillation frequencies or increased sampling rates to achieve desired signal-to-noise ratios. When implementing multi-phase architectures to balance these frequency requirements, the area and power consumption of the digital circuitry may proportionally increase with the number of oscillator phases, creating a constraint on converter area and power efficiency.

### SUMMARY

In accordance with an embodiment, a method includes generating N phases from a ring oscillator circuit having an odd number of stages, where N is an odd integer 3 or greater; encoding the N phases using a combinatorial truncated Gray code encoder circuit to produce M truncated Gray encoded bits, where fewer than 2^{M} Gray codes are used to encode the N phases; converting the M truncated Gray encoded bits to binary using a Gray code to binary encoding circuit to form a binary output; and forming a first difference of the binary output.

In accordance with another embodiment, a device includes a combinatorial truncated Gray code encoder circuit configured to be coupled to outputs of a ring oscillator circuit having an odd number of stages and configured to generate N phases, where N is an odd integer 3 or greater, the combinatorial truncated Gray encoder circuit configured to produce M truncated Gray encoded bits based on the N phases, where fewer than 2^{M} Gray codes are used to encode the N phases; and a Gray code to binary encoding circuit coupled to an output of the combinatorial truncated Gray encoder circuit, the Gray code to binary encoding circuit configured to convert the M truncated Gray encoded bits to binary.

In accordance with a further embodiment, a system includes a microelectromechanical systems (MEMS) microphone; and at least one analog-to-digital converter including: a ring oscillator having a frequency control input coupled to an output of the MEMS microphone, the ring oscillator having an odd number of stages configured to produce N phases, where N is an odd integer 3 or greater, a combinatorial truncated Gray code encoder circuit coupled to outputs of the ring oscillator and configured to produce M truncated Gray encoded bits based on the N phases, where fewer than 2^{M} Gray codes are used to encode the N phases, a Gray code to binary encoding circuit coupled to an output of the combinatorial truncated Gray encoder circuit, the Gray code to binary encoding circuit configured to convert the M truncated Gray encoded bits to binary, and a first difference circuit coupled to an output of the Gray code to binary encoding circuit.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a block diagram of a voltage-controlled oscillator-based analog-to-digital converter according to an embodiment of the present disclosure;

FIG. 2A illustrates timing relationships between ring oscillator waveforms and their corresponding truncated Gray code representations according to an embodiment; and FIG. 2B illustrates various implementations of truncated Gray code sequences according to an embodiment;

FIG. 3A illustrates a schematic diagram of a VCO-ADC according to a specific embodiment; FIG. 3B illustrates timing relationships and truncated Gray code mapping for a seven-phase ring oscillator; FIG. 3C illustrates a conversion table showing the relationship between Gray code and binary code representations for an embodiment; and FIG. 3D illustrates a schematic diagram of a subtractor circuit according to an embodiment;

FIG. 4 illustrates a block diagram of a pseudo-differential microphone system incorporating embodiment VCO-ADCs; and

FIG. 5 illustrates a flowchart of a method according to an embodiment.

Corresponding numerals and symbols in different figures generally refer to corresponding parts unless otherwise indicated. The figures are drawn to clearly illustrate the relevant aspects of the preferred embodiments and are not necessarily drawn to scale. To more clearly illustrate certain embodiments, a letter indicating variations of the same structure, material, or process step may follow a figure number.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

In an embodiment, a frequency-to-digital converter for a voltage-controlled oscillator-based analog-to-digital converter (VCO-ADC) employs a truncated Gray code encoding scheme to process phase outputs from a ring oscillator. The system encodes the phase progression of the ring oscillator using a combinatorial truncated Gray code encoder circuit that produces M Gray encoded bits, where the number of Gray encoded bits is less than the number of oscillator phases (except for the case of a three-phase ring oscillator where the number of Gray encoded bits equals the number of oscillator phases). This encoded output is then processed through a Gray-to-binary conversion circuit and a first difference circuit to generate a digital output representing the oscillator's frequency, as well as the analog input signal being used to modulate the oscillator's frequency. By encoding the phase information before sampling, the system achieves a reduction in the number of flip-flops compared to thermometer-coded FDC implementations, while maintaining robustness against metastability errors due to the Gray code's characteristic of only one bit changing between adjacent states. Hence, the number of flip-flops may scale with the number of Gray code bits instead of the number of oscillator phases in some embodiments. For example, a VCO-ADC having a 59-phase ring oscillator may utilize a thermometer-coded FDC having at least 118 flip-flops, 59 adders and 59 XOR gates. On the other hand, a VCO-ADC having a 59-phase ring oscillator may include only 14 adders and 13 XOR gates according to some embodiments.

The truncated Gray code implementation enables compatibility with single-ended ring oscillators having an odd number of stages, providing additional design flexibility. Because the system performs phase encoding prior to sampling, and because the Gray code ensures only single-bit transitions between adjacent states, the converter maintains reliable operation even when the sampling clock arrives near a phase transition of the ring oscillator. In some embodiments, the ring oscillator's frequency control input may be coupled to an analog signal source (such as a microphone or a sensor) to form a VCO-ADC. In such embodiments, an analog signal provided by the analog signal source is used to modulate an oscillation frequency of the ring oscillator.

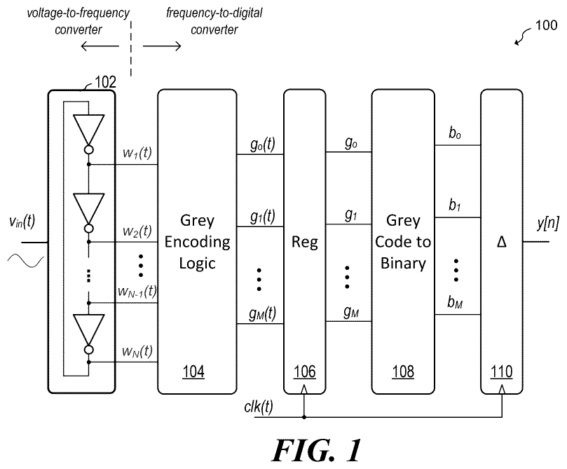

FIG. 1 illustrates a voltage-controlled oscillator-based analog-to-digital converter (VCO-ADC) that transforms an input voltage vin(t) into a digital output y[n] through a series of signal processing stages. The system begins with a ring oscillator 102 that includes an odd number of single-ended inverter stages, which may be implemented as current-starved inverters whose delay characteristics are controllable by input voltage vᵢₙ(t) such that ring oscillator 102 functions as a VCO with input voltage vᵢₙ(t) modulating the oscillator's frequency. Alternatively, the input signal (also referred to as an “analog input signal”) may be a current such that ring oscillator 102 implements a current controlled oscillator (ICO).

In operation, each inverter stage within ring oscillator 102 generates a distinct phase output, denoted as w₁(t) through w_{N}(t), where N represents the total number of phases of ring oscillator 102. These phase signals feed into a truncated Gray code encoder circuit 104 (also referred to as a “combinatorial truncated Gray code encoder circuit”), which implements combinatorial logic to convert the N oscillator phases into M truncated gray-coded output signals, denoted as g₀(t) through g_{M}(t), where M is less than N. In some embodiments, the relationship between the number of oscillator phases N and the number of truncated Gray encoded bits is M=ceil[log₂(2N)], where “ceil” is a ceiling function. For example, in a system with N=3 phases, M=ceil[log2(6)]=ceil[2.58 . . . ]=3 bits. In various embodiments, rounding of M to the nearest integer in the direction of positive infinity makes it possible to use any number of phases in the oscillator when the Gray code is truncated in accordance with the number of oscillator phases N. For example, the Gray code may have 2N states.

Gray code encoding represents sequential binary values such that adjacent numbers differ by only a single bit position, providing an encoding scheme that minimizes transition errors in digital systems. This encoding method differs from standard binary encoding, where multiple bits may change simultaneously between consecutive values. In a Gray code sequence, the transition between any two adjacent numbers involves exactly one bit change, regardless of the total number of bits used in the representation. For example, in a three-bit Gray code sequence, the progression moves through states such as 000→001→011→010→110→111→101→100, in which only one bit position changes between each adjacent pair. This property becomes useful in digital systems where multiple bit transitions can lead to temporary invalid states or metastability issues during sampling operations.

A truncated Gray code represents a subset of a complete Gray code sequence, maintaining the single-bit transition property while using fewer total states than would be available with the full bit width. When encoding N phases from a ring oscillator using M bits, where M=ceil[log₂(2N)], the truncated Gray code uses only the actual number of states to represent the actual phase transitions, omitting unused states. For example, in a system with three oscillator phases having six distinct states, a three-bit truncated Gray code might use states 001→011→010→110→111→101, eliminating two states from the complete eight-state sequence (e.g., 000 and 100) while preserving the single-bit transition property between adjacent valid states. Using a truncated Gray code allows for the efficient coding of N oscillator phases where N is less than 2^{M} and fewer than 2^{M} states are used. This situation arises, for example, when the number of ring-oscillator phases is odd.

The truncated Gray-coded signals are then sampled by register 106, which operates under the control of a system clock signal clk(t) applied at a system clock node coupled to a clock input of register 106. In some embodiments, the frequency of clk(t) is set to be at least twice the maximum frequency of ring oscillator 102. Gray-code-to-binary conversion circuit 108 converts the truncated Gray code to binary format represented as bits b₀ to b_{M}. The final stage of processing occurs in first difference block 110, which computes the difference between successive binary samples to generate the digital output signal y[n]. As shown, first difference block 110 is also clocked by system clock signal clk(t). In some embodiments, digital output signal y[n] is a digital representation of analog input signal vᵢₙ(t).

In various embodiments, the truncated Gray code encoder circuit 104 implements combinatorial logic that transforms the N phase signals from ring oscillator 102 into M truncated Gray-coded outputs. The encoding logic may include multiple combinatorial gates arranged to detect specific phase relationships between the oscillator outputs and generate corresponding Gray code bits. The specific gate arrangements are determined by the selected truncated Gray code sequence, according to examples discussed below.

Register 106 may include, for example, M flip-flops that sample the truncated Gray-coded signals under control of system clock signal clk(t). Each flip-flop captures one bit of the truncated Gray code, with all flip-flops triggered simultaneously by the rising (or falling) edge of system clock clk(t). Each flip-flop may be implemented using flip-flop circuits known in the art.

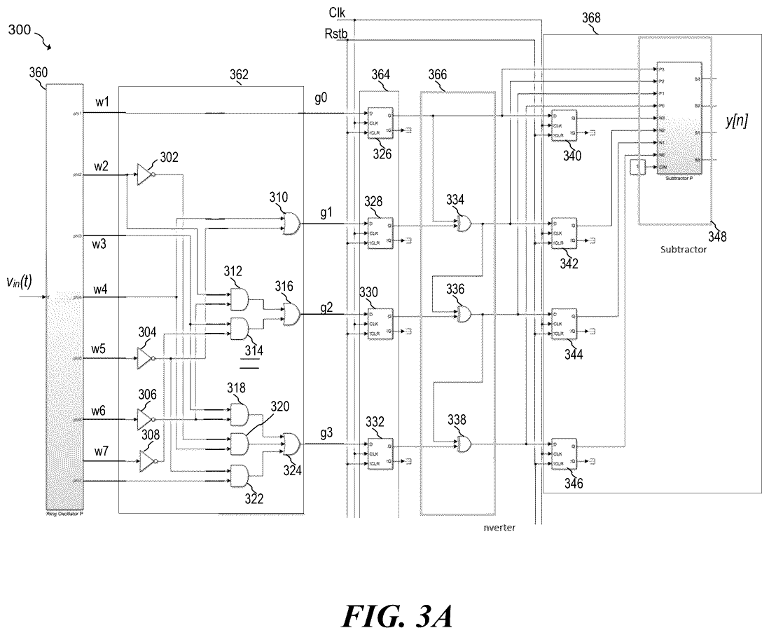

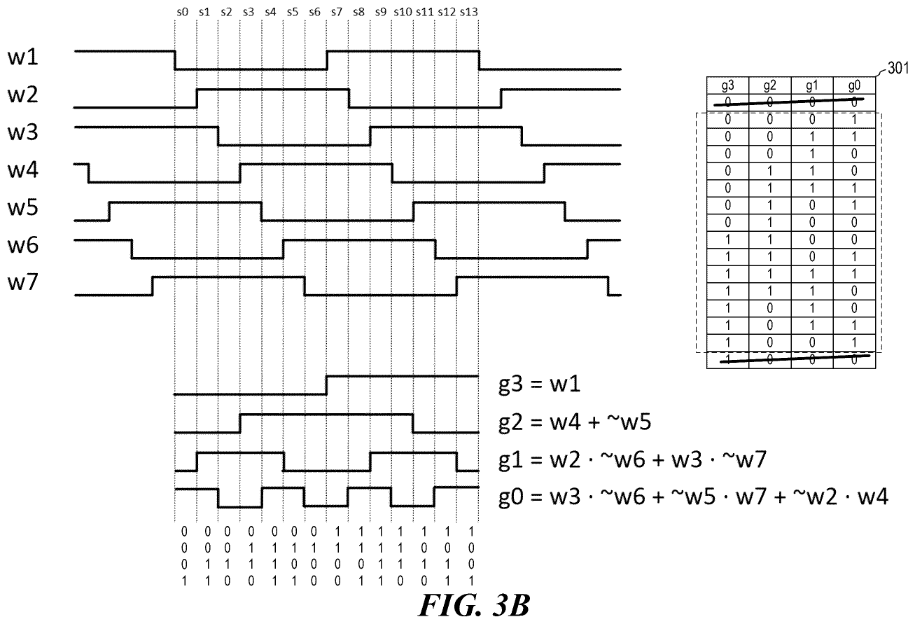

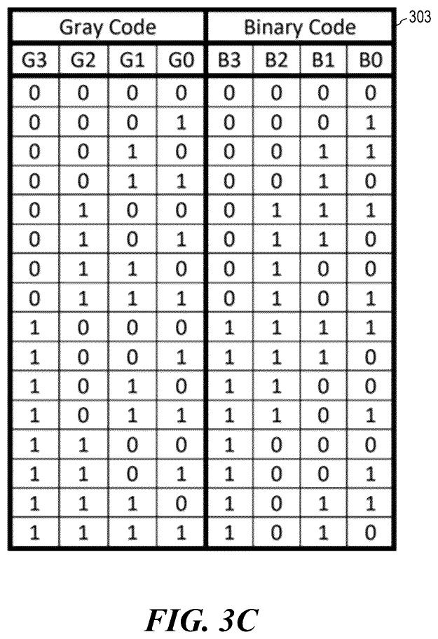

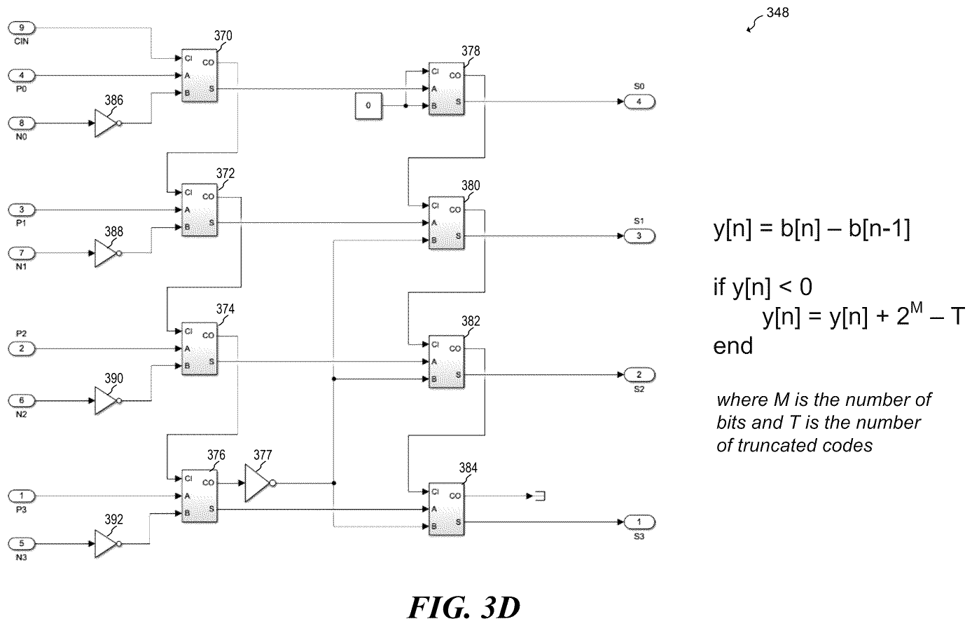

The Gray-code-to-binary conversion circuit 108 may be implemented, for example, using combinatorial logics implemented by a plurality of logic gate arranged to implement the logical function. For example, in one specific implementation, the Gray-to-binary conversion block may be implemented using XOR gates as discussed below in FIG. 3A. Alternatively, other logical implementations may be used.

First difference circuit 110 may be implemented, for example, using a register and an M-bit subtractor that subtracts the previous binary value from the current value. Alternatively, other circuits providing an equivalent function could be used. In some embodiments, in order to correct for the truncated binary sequence resulting from using the truncated Gray code, when the subtraction result is negative, indicating an overflow condition due to the truncated code sequence, the circuit adds 2^{M}-T to the result, where T represents the number of truncated Gray codes. This correction ensures proper handling of the phase count when transitioning through the truncated region of the code space. In other words, first difference circuit 110 may be configured to correct for Gray code truncation by adding 2^{M}-T in response to a first difference between a present output of the Gray-code-to-binary conversion circuit 108 and a previous output of the Gray-code-to-binary conversion circuit 108 being less than zero.

In various embodiments, some or all of the components of VCO-ADC 100 and other embodiments disclosed herein may be implemented on a single monolithic semiconductor integrated circuit, such as a single semiconductor substrate and/or a silicon substrate. VCO-ADC 100 may be fabricated using one of a variety of different semiconductor processes, such as CMOS, FinFET, BiCMOS, SOI, or other types of semiconductor processes.

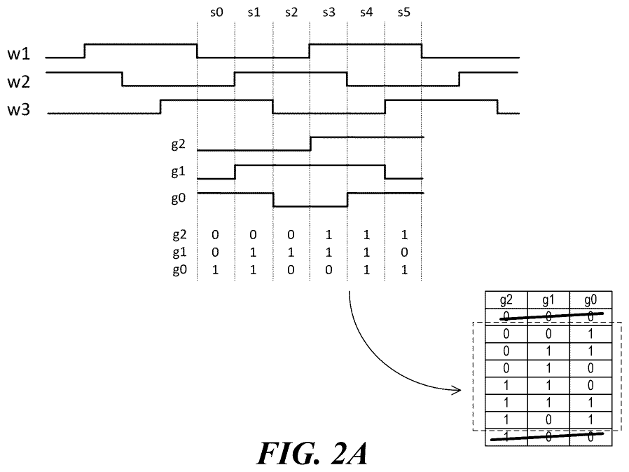

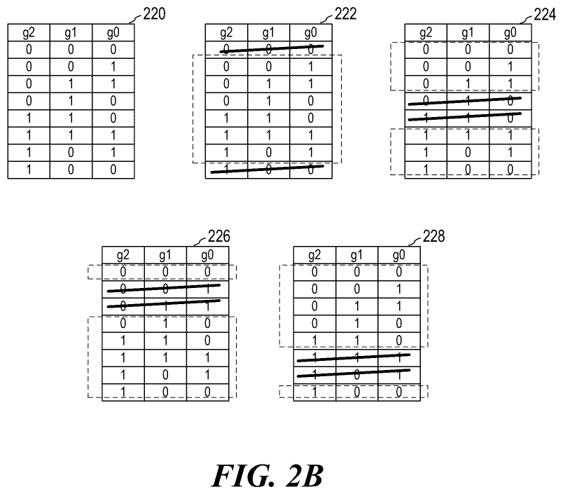

FIG. 2A illustrates timing relationships between ring oscillator waveforms and their corresponding truncated Gray code representations, according to an example embodiment. The figure employs a three-phase ring oscillator as an exemplary implementation, though the principles extend to systems with greater numbers of phases. As shown in the accompanying table, the encoding scheme specifically utilizes a truncated Gray code sequence derived by removing states “000” and “100” from an eight-state, three-bit Gray code, resulting in a six-state sequence that matches the six distinct phases generated by the three-stage oscillator.

The diagram depicts three phase signals w1, w2 and w3 generated by ring oscillator 102, with each signal exhibiting specific phase relationships relative to its neighbors. These waveforms produce 2N=6 six states s0 through s5, with each state having a corresponding truncated three-bit Gray code represented by bits g2, g1 and g0. The truncated Gray code sequence progresses through the states “001” at s0, “011” at s1, “010” at s2, “110” at s3, “111” at s4 and “101” at s5.

FIG. 2B illustrates five distinct three-bit Gray code sequences 220, 222, 224, 226 and 228 that demonstrate different implementations for encoding ring oscillator phases. Sequence 220 represents a complete eight-state Gray code without truncation, providing a reference baseline sequence. In sequence 222, states “000” and “100” are truncated, leaving a sequence of six valid states “001”, “011”, “010”, “110”, “111” and “101” that maintain single-bit transitions between adjacent values. Sequence 224 excludes states “010” and “110” resulting in a sequence of “000”, “001”, “011”, “111”, “101” and “100”; sequence 226 excludes states “001” and “011” resulting in a sequence of “000”, “010”, “110”, “111”, “101” and “100”; and sequence 228 excludes states “111” and “101” resulting in a sequence of “000”, “001”, “011”, “010”, “110” and “100.” It should be understood that these are just a few examples of many possible Gray code patterns. In alternative embodiments, the Gray code sequence may differ by which states are omitted, by how many states are omitted, and/or by how many bits are in the Gray code.

FIGS. 3A through 3D illustrate an example implementation of a VCO-ADC 100 according to a specific embodiment that uses seven oscillator phases and a four-bit Gray code. FIG. 3A illustrates an example schematic diagram of the circuit, FIG. 3B shows an example timing diagram along with a truncated Gray code mapping, FIG. 3C illustrates an example conversion table showing the relationship between the Gray code and the binary code, and FIG. 3D depicts an example of an embodiment first difference circuit.

FIG. 3A illustrates a VCO-ADC 300 according to an embodiment of the present invention. The circuit includes a ring oscillator 360, truncated Gray code encoder circuit 362, register 364, Gray-code-to-binary conversion circuit 366, and first difference circuit 368, which may be used to respectively implement ring oscillator 102, truncated Gray code encoder circuit 104, register 106, Gray-code-to-binary conversion circuit 108, and first difference block 110.

Ring oscillator 360 includes a seven-element single-ended ring oscillator having seven corresponding phase outputs w7 to w1 that are mapped to four truncated Gray-code bits g3 to g0 by truncated Gray code encoder circuit 362. As shown, truncated Gray code encoder circuit 362 comprises logic gates including inverters 302, 304, 306 and 308, OR gates 310, 316 and 324, and AND gates 312, 314, 318, 320 and 322, which implement the following logic equations:

g3=w1

g2=w4 OR ! w5

g1=(w2 AND ! w6) OR (w3 AND ! w7)

G0=(w3 and ! w6) or (! w5 and W7) or (! w2 and W4),

where the symbol “!” denotes an inversion operation.

Register 364 is shown to include D flip-flops 326, 328, 330 and 332 configured to store bits g3 to g0 and having clock inputs configured to receive clock signal Clk and active low reset signal Rstb. Gray-code-to-binary conversion circuit 366 is shown to include exclusive OR gates 334, 336 and 338. The first difference circuit 368 incorporates a register containing D flip-flops 340, 342, 344 and 346 and a subtraction circuit that subtracts the inputs to D flip-flops 340, 342, 344 and 346 from the outputs of D flip-flops 340, 342, 344 to produce output signal y[n]. Each of D flip-flops 340, 342, 344 and 346 is configured to provide a sampled binary output of the output of Gray-code-to-binary conversion circuit 366 and includes inputs configured to receive clock signal Clk and reset signal Rstb. In one example, ring oscillator 360 oscillates at about f₀=2.5 MHz, with a gain of 4 MHz/V, and the frequency of clock signal Clk is about 20 MHz. Alternatively, ring oscillator 360 may operate at different respective frequencies depending on the particular embodiment and its specifications.

It should be appreciated that the specific logic gates and their arrangement within blocks 362, 364, 366 and 368 represent just one exemplary implementation. Alternative embodiments may employ different logically equivalent circuits to achieve the same functionality. For example, while D flip-flops are shown to implement the various registers in blocks 364 and 368, other register elements known in the art may be utilized, including, but not limited to JK or T flip-flops implemented using static or dynamic logic and/or flip-flops using a single clock signals instead of clock signal Clk and reset signal Rstb.

FIG. 3B illustrates timing relationships between the ring oscillator phase signals w7 through w1 and their corresponding truncated Gray encoded outputs g3 through g0 in corresponding states s0 through s13. The timing diagram demonstrates the temporal relationships between the seven phase outputs generated by ring oscillator 360 and the resulting four-bit truncated Gray code produced by the encoding logic. As shown in accompanying table 301, the encoding scheme utilizes a truncated Gray code sequence derived by removing states “0000” and “1000” from a sixteen-state, four-bit Gray code, resulting in a fourteen-state sequence that matches the fourteen distinct phases generated by the seven-stage oscillator. For example, the truncated Gray code sequence progresses through “0001” at state s0, “0011” at state s1, “0010” at state s2, “0110” at state s3, “0111” at state s4, “0101” at state s5, “0100” at state s6, “1100” at state s7, “1101” at state s8, “1111” at state s9, “1110” at state s10, “1010” at state s11, “1011” at state s12 and “1001” at state s13.

FIG. 3C illustrates a Gray code to binary code conversion table representing the Gray code to binary code conversion performed by Gray-code-to binary conversion circuit 366. As shown, table 303 illustrates a comprehensive Gray code to binary mapping conversion scheme. The table demonstrates how each 4-bit Gray code value may correspond to a unique binary representation. As shown, Gray code “0000” converts to binary “0000,” to Gray code “0001” to binary “0001,” Gray code “0010” to binary “0011,” and Gray code “0011” to binary “0010.” The mapping continues with Gray code “0100” converting to binary “0111,” “0101” to “0110,” “0110” to “0100,” “0111” to “0101,” “1000” to “1111,” “1001”to “1110,” “1010” to “1100,” “1011” to “1101,” “1100” to “1000,” “1101” to “1001,” “1110” to “1011,” and finally “1111” to “1010”. In some embodiments, Gray-code-to-binary conversion circuit 366 is not be enabled to covert non-used Gray codes to binary (e.g., Gray codes “0000” and “1000” in the embodiment of FIGS. 3A to 3D.) It should be understood that the Gray code to binary mapping shown in table 303 of FIG. 3C is just one of many possible Gray code to binary mappings. In some embodiments, the Gray code to binary correspondence may be offset by one or more states and/or the binary code may be modified to accommodate a different Gray code sequence.

FIG. 3D illustrates a subtractor circuit 348 that implements a first difference calculation for frequency-to-digital converter 300 shown in FIG. 3A that performs the operation of y[n]=b[n]−b[n−1], with a correction factor of y[n]=y[n]+2^{M}-T applied when y[n]<0, where M represents the number of Gray code bits and T represents the number of truncated Gray codes. For example, in the embodiment of FIGS. 3A-3D, M=4 and T=2.

As shown, the circuit employs two columns of full-adders to subtract the inputs to D flip-flops 340, 342, 344 and 346 from the outputs of D flip-flops 340, 342, 344 and 346 shown in FIG. 3A. The first column of full-adders 370, 372, 374 and 376 performs a binary subtraction, while the second column of full-adders 378, 380, 382 and 384 applies the correction factor.

Inputs P0, P1, P2 and P3 of respective first column full-adders 370, 372, 374 and 376 are respectively coupled to the outputs of D flip-flops 340, 342, 344 and 346. Inputs N0, N1, N2 and N3, which are respectively connected to the outputs of D flip-flops 340, 342, 344 and 346 are respectively coupled to the first column of full-adders 370, 372, 374 and 376 via respective inverters 386, 388, 390 and 392 that perform a one's compliment operation. Carry-in signal CIN is set to logic “high” as shown in FIG. 3A, which effectively causes the binary value at inputs P3 to P0 to be added with the two's compliment of inputs N3 to N0, thereby enabling a binary subtraction.

As shown, the carry-out output CO of full-adder 376 in the first column of full-adders is coupled to the inputs of full-adders 380, 382 and 384 of the second column of full-adders via inverter 377. Hence, the second column of full-adders 378, 380, 382 and 384 add the value T (e.g., 1110 or 14) to the outputs of the first column of full-adders when the carry-out CO output of full-adder 376 is a logic “low,” which signifies that the output of the first column of full-adders represents a number that is less than zero. Otherwise, zero is added to the outputs of the first column of full-adders, which represents digital output value y[n].

It should be understood that the subtractor circuit 348 shown in FIG. 3D is just one of many possible implementations of embodiment subtractor circuits. In alternative embodiments, other functionally equivalent circuitry could be used. For example, the circuitry of subtractor circuit 348 could be adjusted depending on the number of binary bits and the number of truncated Gray code bits.

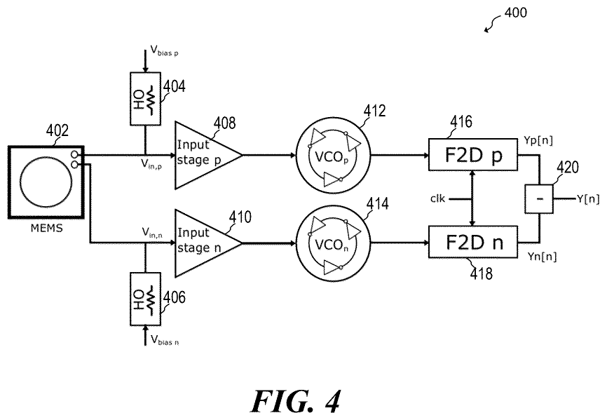

FIG. 4 illustrates a pseudo-differential microphone system 400 according to various implementations that utilizes embodiment VCO-ADC systems. As shown, microphone system 400 includes a differential microelectromechanical systems (MEMS) microphone circuit 402 having a differential output with a positive phase coupled to input stage 408 and a negative phase coupled to input stage 410. In some embodiments, input stages 408 and 410 are voltage amplifiers that have a high input impedance and are configured to buffer the capacitive outputs of MEMS microphone circuit 402. In some embodiments, the bias resistors 404 and 406 are high-value resistors (e.g., hundreds of M Ω to GΩ) that provide bias voltages V_{bias_p} and V_{bias_n} to MEMS microphone circuit 402 to set its sensitivity. The outputs of input stages are respectively coupled to VCOs 412 and 414, which may be implemented using voltage-controlled ring oscillators. In some embodiments, VCOs 412 and 414 have an odd number of single-ended stages that are configured to produce corresponding phase outputs. The outputs of VCOs 412 and 414 are coupled to respective frequency-to-digital converters 416 and 418. In some embodiments, VCOs 412 and 414 and frequency-to-digital converters 416 and 418 may be implemented using VCO-ADCs according to embodiments of the present invention as described with respect to FIGS. 1, 2A, 2B, 3A, 3B, 3C and 3D described above. For example, frequency-to-digital converters 416 and 418 may include truncated Gray encoding logic, registers, Gray-to-binary converters, and subtraction circuits as described in previous figures. A clock signal (clk) is provided to the frequency-to-digital converters 416 and 418 to clock the various registers as described above. Digital subtraction circuit 420 may be used to subtract the output of frequency-to-digital converter 418 from the output of frequency-to-digital converter 416 to produce output y[n].

It should be understood that microphone system 400 is just one of many systems that could be configured to implement embodiment frequency-to-digital converters. For example, embodiment frequency-to-digital converters may be used in other systems such as sensor devices, Internet of Things (IoT) devices, or in high-speed communication systems.

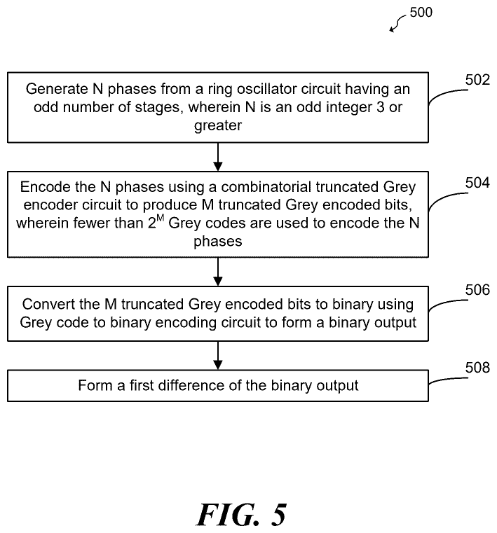

FIG. 5 illustrates a method 500 according to an embodiment that includes steps 502, 504, 506 and 508. As shown, step 502 includes generating N phases from a ring oscillator circuit having an odd number of stages, where N is an odd integer 3 or greater. In some embodiments, step 502 may be implemented using ring oscillator 102 shown in FIG. 1 or ring oscillator 360 shown in FIG. 3A. Step 504 includes encoding the N phases using a combinatorial truncated Gray code encoder circuit to produce M truncated Gray encoded bits. In some embodiments, truncated Gray code encoder circuit 104 of FIG. 1 or truncated Gray code encoder circuit 362 of FIG. 3A may be used to perform this step. In step 506, the M truncated Gray encoded bits are converted to binary using a Gray code to binary encoding circuit to form a binary output, such as Gray-code-to-binary conversion circuit 108 shown in FIG. 1 or Gray-code-to-binary conversion circuit 366 shown in FIG. 3A. Step 508 includes forming a first difference of the binary output, which may be performed by first difference block 110 shown in FIG. 1 or first difference circuit 368 shown in FIG. 3A.

Although FIG. 5 shows example blocks of method 500, in some implementations, method 500 may include additional blocks, fewer blocks, different blocks, or differently arranged blocks than those depicted in FIG. 5. Additionally, or alternatively, two or more of the blocks of method 500 may be performed in parallel.

While the embodiments described herein provided the specific example of single-ended ring oscillators having an odd number of stages, it should be appreciated that embodiment FDCs and VCO-ADCs could also be implemented with differential oscillators having N stages that are not a power of two such that N=/2^{k}, where k is a positive integer and N is even.

Embodiments of the present invention are summarized here. Other embodiments can also be understood from the entirety of the specification and the claims filed herein.

Example 1. A method includes generating N phases from a ring oscillator circuit having an odd number of stages, where N is an odd integer 3 or greater; encoding the N phases using a combinatorial truncated Gray code encoder circuit to produce M truncated Gray encoded bits, where fewer than 2^{M} Gray codes are used to encode the N phases; converting the M truncated Gray encoded bits to binary using a Gray code to binary encoding circuit to form a binary output; and forming a first difference of the binary output.

Example 2. The method of example 1, where performing the first difference includes sampling the binary output using a register to provide a sampled binary output; and subtracting the sampled binary output from the binary output using a subtraction circuit to form a subtracted output.

Example 3. The method of example 2, where subtracting the sampled binary output includes adding 2^{M}-T to the subtracted output in response to the subtracted output being less than zero, where T is a number of codes not included in the M truncated gray encoded bits.

Example 4. The method of any one of examples 1-3, further including sampling the M truncated Gray encoded bits using a register before converting the M truncated Gray encoded bits to binary.

Example 5. The method of any one of examples 1-4, further including modulating an oscillation frequency of the ring oscillator circuit with an analog input signal provided at a frequency control input of the ring oscillator circuit, where the first difference includes a digital representation of the analog input signal.

Example 6. The method of example 5, further including generating the analog input signal using a microphone circuit.

Example 7. The method of example 5 of 6, where the microphone circuit includes a microelectromechanical systems (MEMS) microphone.

Example 8. A device includes a combinatorial truncated Gray code encoder circuit configured to be coupled to outputs of a ring oscillator circuit having an odd number of stages and configured to generate N phases, where N is an odd integer 3 or greater, the combinatorial truncated Gray encoder circuit configured to produce M truncated Gray encoded bits based on the N phases, where fewer than 2^{M} Gray codes are used to encode the N phases; and a Gray code to binary encoding circuit coupled to an output of the combinatorial truncated Gray encoder circuit, the Gray code to binary encoding circuit configured to convert the M truncated Gray encoded bits to binary.

Example 9. The device of example 8, further including a subtraction circuit coupled to the Gray code to binary encoding circuit.

Example 10. The device of example 9, further including a register coupled between the Gray code to binary encoding circuit and the subtraction circuit, where the subtraction circuit includes a first plurality of adder circuits having first inputs coupled to respective outputs of the Gray code to binary encoding circuit and second inputs coupled to respective outputs of the register; and a second plurality of adder circuits coupled to outputs of the first plurality of adder circuits, where the second plurality of adder circuits are configured to add 2^{M}-T to the outputs of the first plurality of adder circuits, where T is a number of codes not included in the M truncated Gray encoded bits.

Example 11. The device of example 9 or 10, further including a first register coupled between the combinatorial truncated Gray code encoder circuit and the Gray code to binary encoding circuit; and a second register coupled between the Gray code to binary encoding circuit and the subtraction circuit, where a clock input of the first register and a clock input of the second register is coupled to a system clock node.

Example 12. The device of any one of examples 8-11, further including the ring oscillator circuit.

Example 13. The device of example 12, where the odd number of stages of the ring oscillator circuit include single-ended stages.

Example 14. The device of any example 12 or 13, where the ring oscillator circuit includes a frequency control input.

Example 15. The device example 14, further including a microphone circuit having an output coupled to the frequency control input of the ring oscillator circuit.

Example 16. The device of example 14, where the microphone circuit includes a microelectromechanical systems (MEMS) microphone.

Example 17. An integrated circuit that includes the device of any of examples 8-16.

Example 18. A system includes a microelectromechanical systems (MEMS) microphone; and at least one analog-to-digital converter including: a ring oscillator having a frequency control input coupled to an output of the MEMS microphone, the ring oscillator having an odd number of stages configured to produce N phases, where N is an odd integer 3 or greater, a combinatorial truncated Gray code encoder circuit coupled to outputs of the ring oscillator and configured to produce M truncated Gray encoded bits based on the N phases, where fewer than 2^{M} Gray codes are used to encode the N phases, a Gray code to binary encoding circuit coupled to an output of the combinatorial truncated Gray encoder circuit, the Gray code to binary encoding circuit configured to convert the M truncated Gray encoded bits to binary, and a first difference circuit coupled to an output of the Gray code to binary encoding circuit.

Example 19. The system of example 18, where the MEMS microphone includes a differential output; and the at least one analog-to-digital converter includes a first analog-to-digital converter coupled to a first node of the differential output, and a second analog-to-digital converter coupled to a second node of the differential output.

Example 20. The system of example 19, further including a subtraction circuit having a first input coupled to an output of the first analog-to-digital converter, and a second input coupled to an output of the second analog-to-digital converter.

Example 21. The system of any one of examples 18-20, where the first difference circuit is configured to correct for Gray code truncation by adding 2^{M}-T in response to a first difference between a present output of the Gray code to binary encoding circuit and a previous output of the Gray code to binary encoding circuit being less than zero, T is a number of codes not included in the M truncated Gray encoded bits.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method comprising:
generating N phases from a ring oscillator circuit having an odd number of stages, wherein N is an odd integer 3 or greater;
encoding the N phases using a combinatorial truncated Gray code encoder circuit to produce M truncated Gray encoded bits, wherein fewer than 2^{M} Gray codes are used to encode the N phases;
converting the M truncated Gray encoded bits to binary using a Gray code to binary encoding circuit to form a binary output; and
forming a first difference of the binary output.

2. The method of claim 1, wherein performing the first difference comprising:
sampling the binary output using a register to provide a sampled binary output; and
subtracting the sampled binary output from the binary output using a subtraction circuit to form a subtracted output.

3. The method of claim 2, wherein subtracting the sampled binary output comprises adding 2^{M}-T to the subtracted output in response to the subtracted output being less than zero, wherein T is a number of codes not included in the M truncated Gray encoded bits.

4. The method of claim 1, further comprising sampling the M truncated Gray encoded bits using a register before converting the M truncated Gray encoded bits to binary.

5. The method of claim 1, further comprising modulating an oscillation frequency of the ring oscillator circuit with an analog input signal provided at a frequency control input of the ring oscillator circuit, wherein the first difference comprises a digital representation of the analog input signal.

6. The method of claim 5, further comprising generating the analog input signal using a microphone circuit.

7. The method of claim 6, wherein the microphone circuit comprises a microelectromechanical systems (MEMS) microphone.

8. A device comprising:
a combinatorial truncated Gray code encoder circuit configured to be coupled to outputs of a ring oscillator circuit having an odd number of stages and configured to generate N phases, wherein N is an odd integer 3 or greater, the combinatorial truncated Gray encoder circuit configured to produce M truncated Gray encoded bits based on the N phases, wherein fewer than 2^{M} Gray codes are used to encode the N phases; and
a Gray code to binary encoding circuit coupled to an output of the combinatorial truncated Gray encoder circuit, the Gray code to binary encoding circuit configured to convert the M truncated Gray encoded bits to binary.

9. The device of claim 8, further comprising a subtraction circuit coupled to the Gray code to binary encoding circuit.

10. The device of claim 9, further comprising a register coupled between the Gray code to binary encoding circuit and the subtraction circuit, wherein the subtraction circuit comprises:
a first plurality of adder circuits having first inputs coupled to respective outputs of the Gray code to binary encoding circuit and second inputs coupled to respective outputs of the register; and
a second plurality of adder circuits coupled to outputs of the first plurality of adder circuits, wherein the second plurality of adder circuits are configured to add 2^{M}-T to the outputs of the first plurality of adder circuits, wherein T is a number of codes not included in the M truncated Gray encoded bits.

11. The device of claim 9, further comprising:
a first register coupled between the combinatorial truncated Gray code encoder circuit and the Gray code to binary encoding circuit; and
a second register coupled between the Gray code to binary encoding circuit and the subtraction circuit, wherein a clock input of the first register and a clock input of the second register is coupled to a system clock node.

12. The device of claim 8, further comprising the ring oscillator circuit.

13. The device of claim 12, wherein the odd number of stages of the ring oscillator circuit comprise single-ended stages.

14. The device of claim 12, wherein the ring oscillator circuit comprises a frequency control input.

15. The device of claim 14, further comprising a microphone circuit having an output coupled to the frequency control input of the ring oscillator circuit.

16. The device of claim 15, wherein the microphone circuit comprises a microelectromechanical systems (MEMS) microphone.

17. An integrated circuit comprising the device of claim 11.

18. A system comprising:
a microelectromechanical systems (MEMS) microphone; and
at least one analog-to-digital converter comprising:
a ring oscillator having a frequency control input coupled to an output of the MEMS microphone, the ring oscillator having an odd number of stages configured to produce N phases, wherein N is an odd integer 3 or greater,
a combinatorial truncated Gray code encoder circuit coupled to outputs of the ring oscillator and configured to produce M truncated Gray encoded bits based on the N phases, wherein fewer than 2^{M} Gray codes are used to encode the N phases,
a Gray code to binary encoding circuit coupled to an output of the combinatorial truncated Gray encoder circuit, the Gray code to binary encoding circuit configured to convert the M truncated Gray encoded bits to binary, and
a first difference circuit coupled to an output of the Gray code to binary encoding circuit.

19. The system of claim 18, wherein:
the MEMS microphone comprises a differential output; and
the at least one analog-to-digital converter comprises:
a first analog-to-digital converter coupled to a first node of the differential output, and
a second analog-to-digital converter coupled to a second node of the differential output.

20. The system of claim 19, further comprising a subtraction circuit having a first input coupled to an output of the first analog-to-digital converter, and a second input coupled to an output of the second analog-to-digital converter.

21. The system of claim 18, wherein the first difference circuit is configured to correct for Gray code truncation by adding 2^{M}-T in response to a first difference between a present output of the Gray code to binary encoding circuit and a previous output of the Gray code to binary encoding circuit being less than zero, wherein T is a number of codes not included in the M truncated Gray encoded bits.
